(19) United States
(12) Patent Application Publication
(10) Pub. No.: US 2021/0294929 A1
(43) Pub. Date: Sep. 23, 2021

(54) ACCURACY EVALUATION APPARATUS AND ACCURACY EVALUATION METHOD

(71) Applicant: Honda Motor Co., Ltd., Tokyo (JP)

(72) Inventors: Toyokazu Kumazawa, Hagagun (JP); Ichiro Kono, Hagagun (JP); Hayato Ide, Hagagun (JP)

(21) Appl. No.: 17/200,814

(22) Filed: Mar. 13, 2021

(30) Foreign Application Priority Data
Mar. 18, 2020 (JP) 2020-047324

(51) Int. Cl. G06F 30/12; G06T 7/00; G06T 11/00

(52) U.S. Cl. CPC G06F 30/12; G06T 2207/30164; G06T 11/00; G06T 7/001

(57) ABSTRACT

An accuracy evaluation apparatus evaluates accuracy of coupling portion where first component having first coupling surface and second component having second coupling surface are coupled to each other. The apparatus includes: display unit; and CPU and memory. The CPU is configured to perform: acquiring design data and measurement data of the components; calculating error between design reference point on the coupling surfaces in the design data and reference points on the coupling surfaces corresponding to the design reference point in the measurement data; and calculating interference degree at the design reference point when coupling components based on the error. The display unit displays design model of the components based on the design data and superimposes indicator representing the interference degree on the design model at the design reference point.

### CROSS-REFERENCE TO RELATED APPLICATION

This application is based upon and claims the benefit of priority from Japanese Patent Application No. 2020-047324 filed on Mar. 18, 2020, the content of which is incorporated herein by reference.

### BACKGROUND OF THE INVENTION

### Field of the Invention

This invention relates to an accuracy evaluation apparatus and accuracy evaluation method for evaluating accuracy of a coupling portion between a first component and a second component coupled to each other.

### Description of the Related Art

Conventionally, there has been known a device in which point group data obtained by measuring the shape of an actual component is associated with design data of the component (for example, see JP 2008-76384 A). In the device described in JP 2008-76384 A, a characteristic value representing a shape is calculated for the point group data around a point of interest, and the calculated characteristic value is compared with a characteristic value obtained by the design data to group and associate the point group data for each element of the design data.

However, in the device described in JP 2008-76384 A, since the point group data is associated corresponding to the entire element such as a plane, an error with respect to a design reference position cannot be easily grasped when accuracy of a coupling portion where the components are coupled to each other is evaluated.

### SUMMARY OF THE INVENTION

An aspect of the present invention is an accuracy evaluation apparatus configured to evaluate an accuracy of a coupling portion where a first component having a first coupling surface and a second component having a second coupling surface are coupled to each other through the first coupling surface and the second coupling surface. The apparatus includes: a display unit; and a CPU and a memory coupled to the CPU. The CPU is configured to perform: acquiring design data of the first component and the second component and premeasured measurement data of the first component and the second component; calculating a first error between a design reference point predetermined as a single point on the first coupling surface and the second coupling surface in the design data and a first reference point on the first coupling surface corresponding to the design reference point in the measurement data and a second error between the reference point and a second reference point on the second coupling surface corresponding to the design reference point in the measurement data based on the design data and the measurement data acquired; and calculating an interference degree at the design reference point when coupling the first component and the second component based on the first error and the second error calculated. The display unit is configured to display a design model of the first component and the second component based on the design data acquired by the CPU, and configured to display an indicator representing the interference degree calculated by the CPU so that the indicator is superimposed on the design model at the design reference point.

Another aspect of the present invention is an accuracy evaluation apparatus configured to evaluate an accuracy of a coupling portion where a first component having a first coupling surface and a second component having a second coupling surface are coupled to each other through the first coupling surface and the second coupling surface. The apparatus includes: a display unit; and a CPU and a memory coupled to the CPU. The CPU is configured to function as: a data acquisition unit configured to acquire design data of the first component and the second component and premeasured measurement data of the first component and the second component; an error calculation unit configured to calculate a first error between a design reference point predetermined as a single point on the first coupling surface and the second coupling surface in the design data and a first reference point on the first coupling surface corresponding to the design reference point in the measurement data and a second error between the reference point and a second reference point on the second coupling surface corresponding to the design reference point in the measurement data based on the design data and the measurement data acquired by the data acquisition unit; and an interference degree calculation unit configured to calculate an interference degree at the design reference point when coupling the first component and the second component based on the first error and the second error calculated by the error calculation unit. The display unit is configured to display a design model of the first component and the second component based on the design data acquired by the CPU, and configured to display an indicator representing the interference degree calculated by the CPU so that the indicator is superimposed on the design model at the design reference point.

Another aspect of the present invention is an accuracy evaluation method configured to evaluate an accuracy of a coupling portion where a first component having a first coupling surface and a second component having a second coupling surface are coupled to each other through the first coupling surface and the second coupling surface. The method includes: acquiring design data of the first component and the second component and premeasured measurement data of the first component and the second component; calculating a first error between a design reference point predetermined as a single point on the first coupling surface and the second coupling surface in the design data and a first reference point on the first coupling surface corresponding to the design reference point in the measurement data and a second error between the reference point and a second reference point on the second coupling surface corresponding to the design reference point in the measurement data based on the design data and the measurement data acquired; calculating an interference degree at the design reference point when coupling the first component and the second component based on the first error and the second error calculated; displaying a design model of the first component and the second component based on the design data acquired; and displaying an indicator representing the interference degree calculated so that the indicator is superimposed on the design model at the design reference point.

### BRIEF DESCRIPTION OF THE DRAWINGS

The objects, features, and advantages of the present invention will become clearer from the following description of embodiments in relation to the attached drawings, in which:

FIG. 1 is a side view schematically showing an example of a coupling portion to which an accuracy evaluation apparatus according to an embodiment of the present invention is applied;

FIG. 2 is a diagram for explaining design data and measurement data;

FIG. 3 is a block diagram showing an overall configuration of an accuracy evaluation system including the accuracy evaluation apparatus according to the embodiment of the present invention;

FIG. 4 is a diagram for explaining a single component error calculated by an error calculation unit in FIG. 3;

FIG. 5 is a flowchart showing an example of an error calculation process executed by the accuracy evaluation apparatus according to the embodiment of the present invention;

FIG. 6A is a diagram showing an example of a characteristic value for a first component calculated by the error calculation unit in FIG. 3;

FIG. 6B is a diagram showing an example of a characteristic value for a second component calculated by the error calculation unit in FIG. 3;

FIG. 7A is a diagram for explaining calculation of an interference degree by an interference degree calculation unit in FIG. 3, when both directions of the single component error of the first, second components cause interference in the coupling portion;

FIG. 7B is the same diagram as FIG. 7A, when both directions of the single component error of the first, second components cause gap in the coupling portion;

FIG. 7C is the same diagram as FIG. 7A, when directions of the single component error of the first, second components respectively cause interference and gap in the coupling portion;

FIG. 7D is the same diagram as FIG. 7A, when directions of the single component error of the first, second components respectively cause gap and interference in the coupling portion;

FIG. 8 is a diagram showing an example of the interference degree calculated by the interference degree calculation unit in FIG. 3;

FIG. 9 is a diagram for explaining a display mode of an indicator displayed on a display unit in FIG. 3;

FIG. 10 is a diagram showing an example of the indicator displayed on the display unit in FIG. 3;

FIG. 11 is a flowchart showing an example of an interference degree calculation process executed by the accuracy evaluation apparatus according to the embodiment of the present invention;

FIG. 12 is a diagram showing an example of a statistics display displayed on the display unit in FIG. 3; and

FIG. 13 is a diagram showing another example of the statistics display displayed on the display unit in FIG. 3.

### DETAILED DESCRIPTION OF THE INVENTION

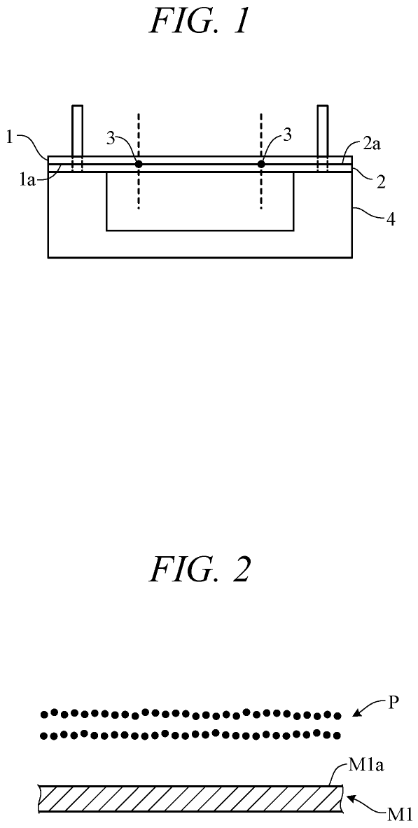

An embodiment of the present invention is explained with reference to FIG. 1 to FIG. 13 in the following. An accuracy evaluation apparatus according to an embodiment of the present invention evaluates accuracy of a coupling portion between a first component and a second component coupled to each other. FIG. 1 is a side view schematically showing an example of the coupling portion, and shows a coupling portion between a first component 1 and a second component 2 coupled to each other. The first component 1 and the second component 2 are, for example, constituent components constituting a finished product manufactured in a factory of a finished product manufacturer, and are manufactured by a component manufacturer, delivered to the factory of the finished product manufacturer, and used for manufacturing the finished product.

As shown in FIG. 1, the first component 1 and the second component 2 are coupled to each other by being welded through a first coupling surface 1a of the first component 1 and a second coupling surface 2a of the second component 2, for example, at a plurality of weld spots 3. More specifically, the first component 1 and the second component 2 are coupled by being welded at a plurality of the weld spots 3 predetermined by, for example, an industrial robot that is fixed by a welding jig 4 installed at a predetermined position and operates according to a predetermined program.

A finished product including the first component 1 and the second component 2 is designed by using a design device such as a three-dimensional CAD device, and design data showing a design shape (design model) of the finished product including the first component 1 and the second component 2 is generated. For example, in a three-dimensional fixed coordinate system in which a center of gravity of the finished product is an origin, a horizontal direction corresponds to X and Y axes, and a vertical direction is a Z axis, the design shape of the finished product including the first component 1 and the second component 2 is specified. Installation positions of the weld spot 3 and the welding jig 4 shown in FIG. 1 are also specified in the fixed coordinate system by the design data.

Therefore, the accuracy of the coupling portion between the first component 1 and the second component 2 shown in FIG. 1 becomes higher as an error (single component error) of an actual shape with respect to the design shape of each of the first component 1 and the second component 2 in the fixed coordinate system becomes smaller, and becomes lower as the single component error becomes larger. As a mode in which the accuracy of the coupling portion is lowered, an interference occurs at the coupling portion when the single component error of the first component 1 and the second component 2 occurs in a direction toward the coupling portion, and a gap occurs in the coupling portion when the single component error of the first component 1 and the second component 2 occurs in a direction away from the coupling portion.

The single component error of each of the first component 1 and the second component 2 is measured using a measuring device such as a laser type or optical three-dimensional measuring instrument, and measurement data showing an actual shape of each of the first component 1 and the second component 2 is generated. More specifically, as shown in FIG. 1, a surface shape of each of the first component 1 and the second component 2 in a state of being fixed by the welding jig 4 in the same manner as during welding is measured by the measuring device, and measurement data showing the shape in the fixed coordinate system is generated.

FIG. 2 is a diagram for explaining design data and measurement data, and shows an example of design data and measurement data for the first coupling surface 1a of the first component 1. As shown in FIG. 2, the design data is represented as a first coupling surface M1a of a first component M1, which is a design model. The measurement data is represented as a point group P (point group data) of a measurement point having three-dimensional coordinates (X, Y, Z) in a fixed coordinate system when the actual first coupling surface 1a of the first component 1 is measured by a measuring device.

Since the point group data includes information of three-dimensional coordinates of an enormous number of measurement points according to a resolution of the measuring device, a data capacity of the point group data is large, and it takes time to display the point group P on a display. Therefore, for example, when an error with respect to the design model at each measurement point is calculated and the accuracy of the coupling portion between the first component 1 and the second component 2 is visually evaluated by color map display according to the error or the like, time is required each time the accuracy of the coupling portion of a pair of the first component 1 and the second component 2 is evaluated.

However, for example, in a trial manufacture stage of a finished product in a factory, since it is necessary to evaluate the accuracy of the coupling portions of a plurality of pairs of the first component 1 and the second component 2 within a limited period of time, it is necessary to shorten time required for evaluating the accuracy of the coupling portion of the pair of the first component 1 and the second component 2. Thus, in the present embodiment, the accuracy evaluation apparatus is configured as follows so that time required for visually evaluating the accuracy of the coupling portion between the first component and the second component coupled to each other can be shortened to easily grasp an error with respect to a design reference position.

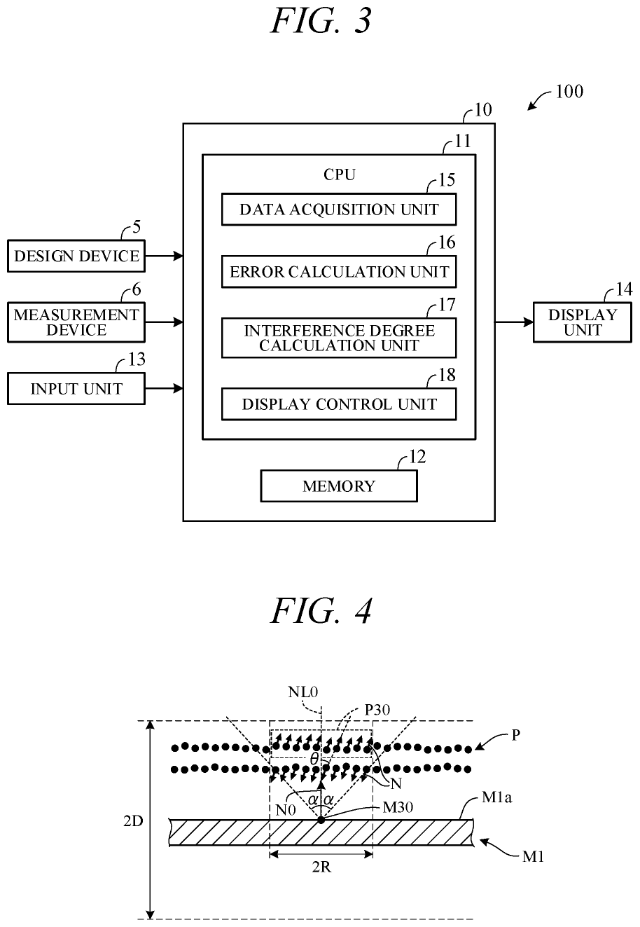

FIG. 3 is a block diagram showing an overall configuration of an accuracy evaluation system 100 including an accuracy evaluation apparatus (hereinafter, the apparatus) 10 according to an embodiment of the present invention. As shown in FIG. 3, the accuracy evaluation system 100 has a design device 5 that generates design data of a finished product including the first component 1 and the second component 2, a measuring device 6 that measures actual shapes of the first component 1 and the second component 2, and the apparatus 10.

The apparatus 10 evaluates the single component error of the first component 1 and the second component 2 and the accuracy of the coupling portion. The apparatus 10 includes a CPU 11, a memory 12 such as ROM and RAM, and a computer having I/O, other peripheral circuits, and the like, and has an input unit 13 such as a keyboard, a mouse, and a touch panel, and a display unit 14 such as a liquid crystal. The CPU 11 functions as a data acquisition unit 15, an error calculation unit 16, an interference degree calculation unit 17, and a display control unit 18. Each function of the CPU 11 such as the interference degree calculation unit 17 and the display control unit 18 may be configured as a function of a CPU of another system that shares the memory 12.

The data acquisition unit 15 acquires design data generated by the design device 5 and measurement data generated by the measuring device 6. The design data and the measurement data acquired by the data acquisition unit 15 are stored in the memory 12.

FIG. 4 is a diagram for explaining the single component error calculated by the error calculation unit 16, and shows an example of the design data and the measurement data for the first component 1. The error calculation unit 16 calculates the single component error of each of the first component 1 and the second component 2 in the fixed coordinate system based on the design data and the measurement data acquired by the data acquisition unit 15.

As shown in FIG. 4, on the first coupling surface M1a of the first component M1 on the design data, n (only one point is shown) design reference points M30 corresponding to the n (multiple) weld spots 3 are set. Each of the design reference points M30 is set with three-dimensional coordinates (X0, Y0, Z0) as a welding target position in the fixed coordinate system. As a welding target direction in the fixed coordinate system, a unit normal vector NO (i0, j0, k0) in a direction away from the first coupling surface M1a along a normal NL0 of the first coupling surface M1a at the design reference point M30 is set.

As shown in FIG. 4, the error calculation unit 16 extracts a point group P30 corresponding to the design reference point M30 from the point group P of all the measurement points. Specifically, the point group within a predetermined distance R (for example, 2.5 mm) from the normal NL0 and within a predetermined distance D (for example, 10 mm) from the first coupling surface M1a is extracted. In addition, for each measurement point of the extracted point group, each point group unit normal vector N (i, j, k) in a direction away from the first coupling surface 1a along a normal of the first coupling surface 1a at the measurement point is calculated. For example, each point group unit normal vector N along a normal of a plane passing through three nearby measurement points including the measurement point is calculated. Then, the point group in which an angle θ1 formed by the unit normal vector NO and each of the point group unit normal vectors N is within a predetermined angle α (for example, 45°) is extracted as the point group P30 corresponding to the design reference point M30.

The error calculation unit 16 calculates, based on the three-dimensional coordinates (X, Y, Z) of each measurement point of the extracted point group P30, three-dimensional coordinates (X1, Y1, Z1) of a first reference point M31 on the first coupling surface 1a corresponding to the design reference point M30. For example, an arithmetic mean value of the three-dimensional coordinates of each measurement point of the point group P30 is calculated as the three-dimensional coordinates of the first reference point M31.

In addition, the error calculation unit 16 calculates the single component error of the first component 1 based on the three-dimensional coordinates (X0, Y0, Z0) of the design reference point M30 and the three-dimensional coordinates (X1, Y1, Z1) of the first reference point M31. That is, by the following equation (i), a distance a between the design reference point M30 and the first reference point M31 is calculated as a magnitude of the single component error of the first component 1. By the following equations (ii) to (iv), a unit normal vector N1 (i1, j1, k1) in a direction from the design reference point M30 to the first reference point M31 is calculated as a direction of the single component error of the first component 1.

a=((X1−X0)²+(Y1−Y0)²+(Z1−Z0)²)^{1/2} (i)

i1=(1/a)(X1−X0) (ii)

j1=(1/a)(Y1−Y0) (iii)

k1=(1/a)(Z1−Z0) (iv)

The error calculation unit 16 calculates the three-dimensional coordinates of the first reference points M31(1) to M31(n) on the corresponding first coupling surface 1a for the design reference points M30(1) to M30(n) corresponding to the n weld spots 3. Magnitudes a(1) to a(n) of the single component error of the first component 1 and directions N1(1) to N1(n) are calculated. Similarly for the second component 2, the three-dimensional coordinates of second reference points M32(1) to M32(n) on the second coupling surface 2a corresponding to the design reference points M30(1) to M30(n) are calculated, and magnitudes b(1) to b(n) of the single component error of the second component 2 and directions N2(1) to N2(n) are calculated.

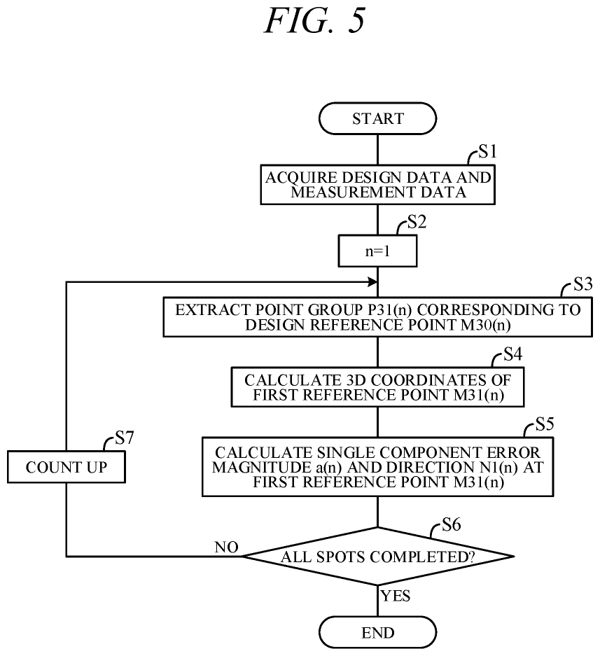

FIG. 5 is a flowchart showing an example of an error calculation process executed by the apparatus 10, and shows an example of a process of calculating the single component error of the first component 1 executed by the CPU 11 in accordance with a program stored in advance in the memory 12. The process shown in the flowchart of FIG. 5 is started when the design data and the measurement data of the first component 1 are input to the apparatus 10, for example.

As shown in FIG. 5, first, in S1 (S: process step), the design data and the measurement data of the first component 1 are acquired. Next, in S2, the design reference point M30(1) corresponding to the first weld spot 3 is specified. Next, in S3, a point group P30(1) corresponding to the design reference point M30(1) is extracted. Next, in S4, three-dimensional coordinates (X1(1), Y1(1), Z1(1)) of the first reference point M31(1) are calculated. Next, in S5, the magnitude a(1) of the single component error and the direction N1(1) at the first reference point M31(1) with respect to the design reference point M30(1) are calculated. Next, in S6, it is determined whether or not the calculation of all the n weld spots 3 has been completed. When it is determined to be NO in S6, the design reference point M30(n) corresponding to the next weld spot 3 is specified in S7, and the process returns to S3. On the other hand, when it is determined to be YES in S6, the process ends.

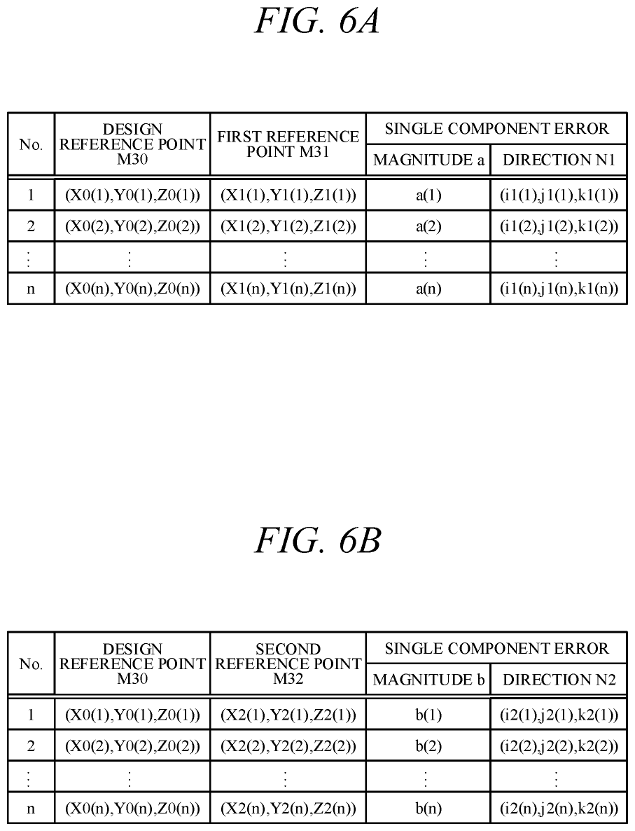

The first reference point M31, the three-dimensional coordinates of the second reference point M32, the magnitudes a and b of the single component errors of the first component 1 and the second component 2, and the directions N1 and N2 calculated by the error calculation unit 16 are stored as characteristic values for each of the n weld spots 3 in the memory 12. FIG. 6A and FIG. 6B are diagrams showing an example of the characteristic value for each of the n weld spots 3 of each of the first component 1 and the second component 2 calculated by the error calculation unit 16 and stored in the memory 12. As shown in FIG. 4, only the point group P30 around the weld spot 3 is extracted from the enormous number of point groups P, and as shown in FIG. 6A and FIG. 6B, the extracted point group P is converted into the characteristic value for each of the n weld spots 3 and stored in the memory 12, so that the data capacity of the point group data can be compressed.

The interference degree calculation unit 17 of FIG. 3 calculates an interference degree I at the design reference point M30 when the first component 1 and the second component 2 are coupled, based on the characteristic values (FIG. 6A and FIG. 6B) of the first component 1 and the second component 2 calculated by the error calculation unit 16 and stored in the memory 12. That is, regarding the design reference points M30(1) to M30(n) corresponding to the n weld spots 3, interference degrees I(1) to I(n) at the time of coupling the first component 1 and the second component 2 are calculated.

The interference degree I is a value indicating a size (distance) of a gap generated between the first coupling surface 1a and the second coupling surface 2a when the first component 1 and the second component 2 are coupled as shown in FIG. 1, and indicates the accuracy of the coupling portion. The smaller an absolute value of the interference degree I, the higher the accuracy of the coupling portion, and the larger the absolute value of the interference degree I, the lower the accuracy of the coupling portion. A positive interference degree I indicates that a gap is generated in the coupling portion, and a negative interference degree I indicates that interference is generated in the coupling portion.

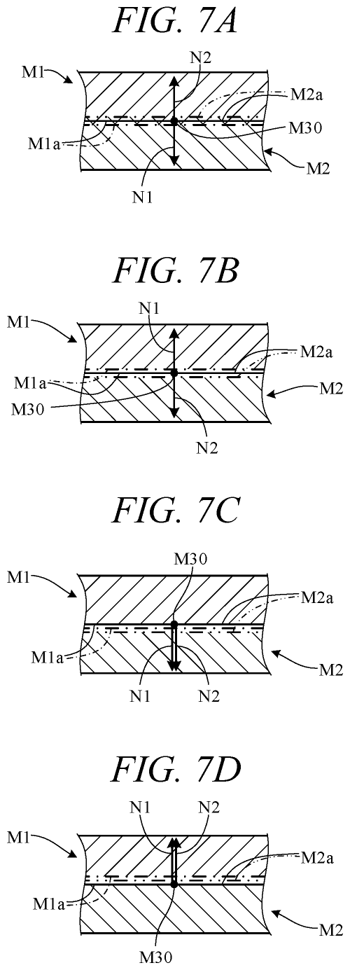

FIG. 7A to FIG. 7D are diagrams for explaining the calculation of the interference degree I by the interference degree calculation unit 17, and show the coupling portion between the first component M1 and the second component M2, the design reference point M30, and the directions N1 and N2 of the single component error of the first component 1 and the second component 2 on the design data. FIG. 7A to FIG. 7D show only components k1 and k2 orthogonal to a coupling surface at the design reference point M30 among the components in the directions N1 (i1, j1, k1) and N2 (i2, j2, k2) of the single component error, and explain a relationship between the directions N1 and N2, such as forward and reverse.

As shown in FIG. 7A, when the directions N1 and N2 of the single component error of the first component 1 and the second component 2 are opposite to each other, and both directions cause interference to occur in the coupling portion, the interference degree calculation unit 17 calculates the interference degree I by the following equation (v).

I=(−a)+(−b) (v)

As shown in FIG. 7B, when the directions N1 and N2 of the single component error of the first component 1 and the second component 2 are opposite to each other, and both directions generate a gap in the coupling portion, the interference degree calculation unit 17 calculates the interference degree I by the following equation (vi).

I=a+b (vi)

As shown in FIG. 7C, when the directions N1 and N2 of the single component error of the first component 1 and the second component 2 are the same, the direction N1 causes interference to occur in the coupling portion, and the direction N2 generates a gap in the coupling portion, the interference degree calculation unit 17 calculates the interference degree I by the following equation (vii).

I=(−a)+b (vii)

As shown in FIG. 7D, when the directions N1 and N2 of the single component error of the first component 1 and the second component 2 are the same, the direction N1 generates a gap in the coupling portion, and the direction N2 causes interference to occur in the coupling portion, the interference degree calculation unit 17 calculates the interference degree I by the following equation (viii).

I=a+(−b) (viii)

Regarding the design reference points M30(1) to M30(n) corresponding to the n weld spots 3, the interference degree calculation unit 17 calculates the interference degrees I(1) to I(n) at the time of coupling the first component 1 and the second component 2. That is, the interference degree calculation unit 17 calculates the interference degrees I(1) to I(n) corresponding to the n weld spots 3 based on a relationship between the directions N1(1) to N1(n) of the single component error of the first component 1 corresponding to the design reference points M30(1) to M30(n) and the directions N2(1) to N2(n) of the single component error of the second component 2.

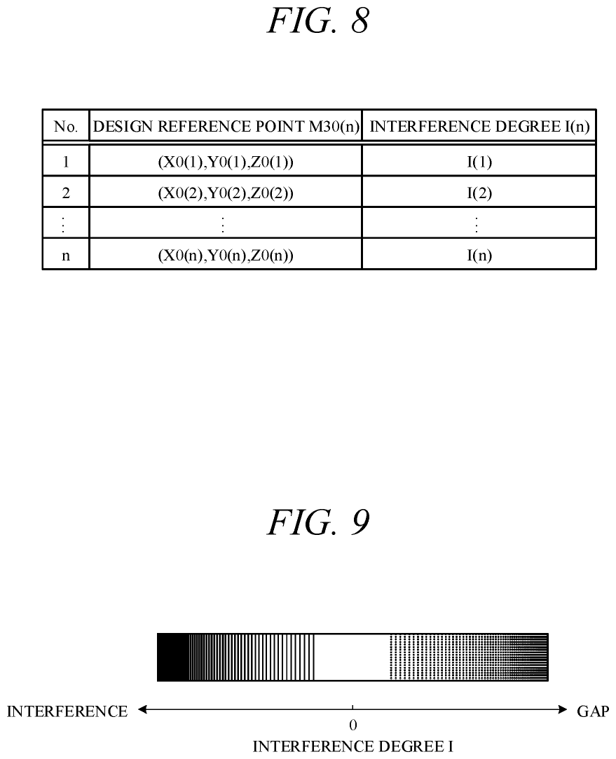

FIG. 8 is a diagram showing an example of the interference degrees I(1) to I(n) for each of the n weld spots 3 at the time of coupling the first component 1 and the second component 2, which are calculated by the interference degree calculation unit 17 and stored in the memory 12. As shown in FIG. 8, the interference degree I calculated by the interference degree calculation unit 17 is stored as the characteristic value for each of the weld spots 3 in the memory 12.

The display control unit 18 of FIG. 3 controls display of the display unit 14 so as to display the design model of the finished product including the first component 1 and the second component 2, based on the design data acquired by the data acquisition unit 15 and stored in the memory 12. The display control unit 18 further controls the display of the display unit 14 so that an indicator MI representing the interference degree I for each of the weld spots 3 is displayed so as to be superimposed on a position of the design reference point M30 of the design model, based on the characteristic value for each of the weld spots 3 calculated by the interference degree calculation unit 17 and stored in the memory 12.

FIG. 9 is a diagram for explaining a display mode of the indicator MI displayed on the display unit 14. The indicator MI is displayed in a different manner according to the interference degree I for each of the weld spots 3. For example, as shown in FIG. 9, the negative interference degree I indicating that interference occurs in the coupling portion is represented by a display color of a warm color system, the positive interference degree I indicating that a gap is generated in the coupling portion is represented by a display color of a cold color system, and the larger the absolute value of the interference degree I, the darker the display color is.

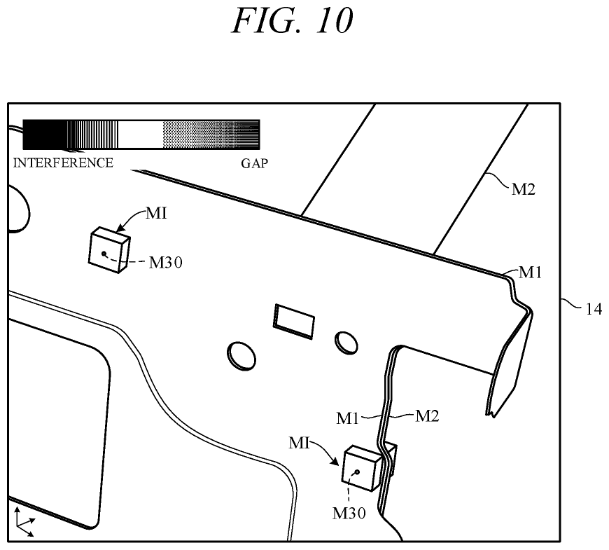

FIG. 10 is a diagram showing an example of the indicator MI displayed on the display unit 14, and shows a plurality of (two in the figure) the indicators MI simultaneously displayed so as to be superimposed on a plurality of (two in the figure) design reference points M30 of the design model in the three-dimensional fixed coordinate system. As shown in FIG. 10, the indicator MI is displayed in a display color corresponding to the interference degree I as a three-dimensional figure such as a cube centered at the design reference point M30 in the fixed coordinate system and having a side surface parallel to the coupling surface at the design reference point M30.

As shown in FIG. 10, since the indicator MI indicating the interference degree I for each of the weld spots 3 is displayed so as to be superimposed on the design model of the finished product including the first component 1 and the second component 2, the accuracy of the coupling portion can be intuitively grasped and evaluated. By switching the viewpoint when the design model is displayed and the display and non-display of each constituent component, the accuracy of the coupling portion located on a back side of each constituent component can also be easily grasped.

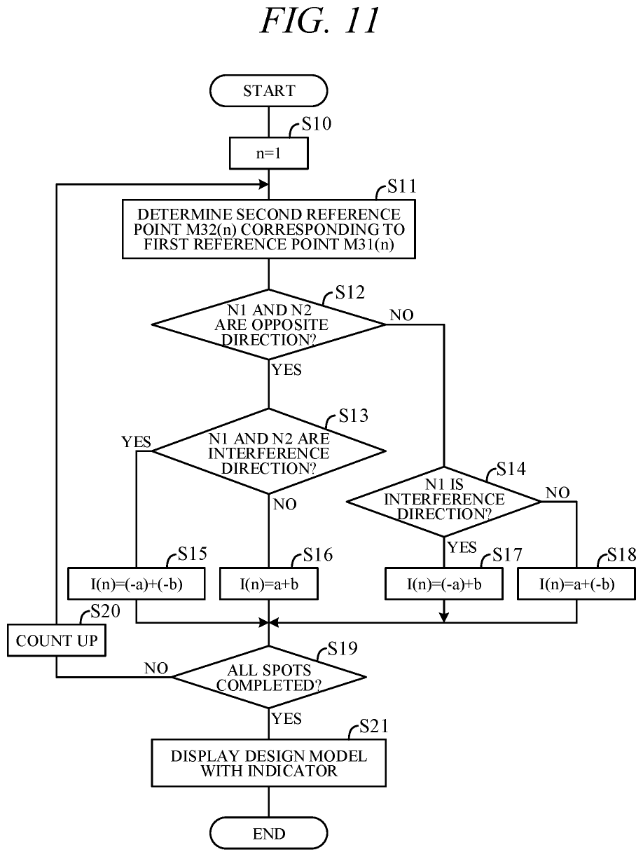

FIG. 11 is a flowchart showing an example of an interference degree calculation process executed by the apparatus 10, and shows an example of a process of calculating the interference degree I at the time of coupling the first component 1 and the second component 2 executed by the CPU 11 in accordance with a program stored in advance in the memory 12. The process shown in the flowchart of FIG. 11 is executed following the process shown in the flowchart of FIG. 5, for example.

As shown in FIG. 11, first, in S10, the first reference point M31(1) corresponding to the first weld spot 3 is specified. Next, in S11, the second reference point M32(1) corresponding to the first reference point M31(1) is determined. Next, in S12, it is determined whether or not the direction N1(1) of the single component error of the first component 1 is opposite to the direction N2(1) of the single component error of the second component 2. When it is determined to be YES in S12, the process proceeds to S13, and when it is determined to be NO, the process proceeds to S14.

In S13, it is determined whether or not both the directions N1(1) and N2(1) of the single component error of the first component 1 and the second component 2 are directions causing interference to occur in the coupling portion. When it is determined to be YES in S13, the process proceeds to S15, and the interference degree I(1) is calculated by the equation (v). On the other hand, when it is determined to be NO in S13, the process proceeds to S16, and the interference degree I(1) is calculated by the equation (vi).

In S14, it is determined whether or not the direction N1(1) of the single component error of the first component 1 is the direction causing interference to occur in the coupling portion. When it is determined to be YES in S14, the process proceeds to S17, and the interference degree I(1) is calculated by the equation (vii). On the other hand, when it is determined to be NO in S14, the process proceeds to S18, and the interference degree I(1) is calculated by the equation (viii).

Next, in S19, it is determined whether or not the calculation for the first reference point M31 corresponding to all the n weld spots 3 has been completed. When it is determined to be NO in S19, the first reference point M31(n) corresponding to the next weld spot 3 is specified in S20, and the process returns to S11. When it is determined to be YES in S19, the process proceeds to S21, and the display of the display unit 14 is controlled so that the indicator MI representing the interference degree I for each of the weld spots 3 calculated in S15 to S18 is displayed so as to be superimposed on the design model.

The single component error of each constituent component calculated by the error calculation unit 16 and the interference degree I of the coupling portion calculated by the interference degree calculation unit 17 can be statistically processed and displayed for each production lot of the first component 1 and the second component 2. For example, the statistics display is performed for each production lot of the first component 1 and the second component 2 manufactured by a component manufacturer.

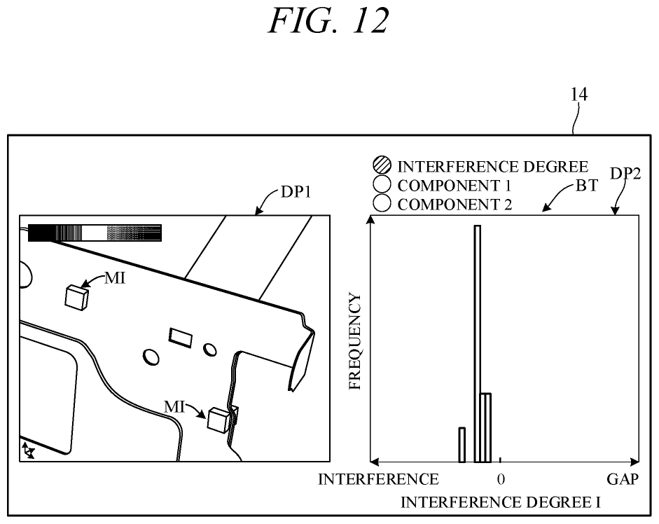

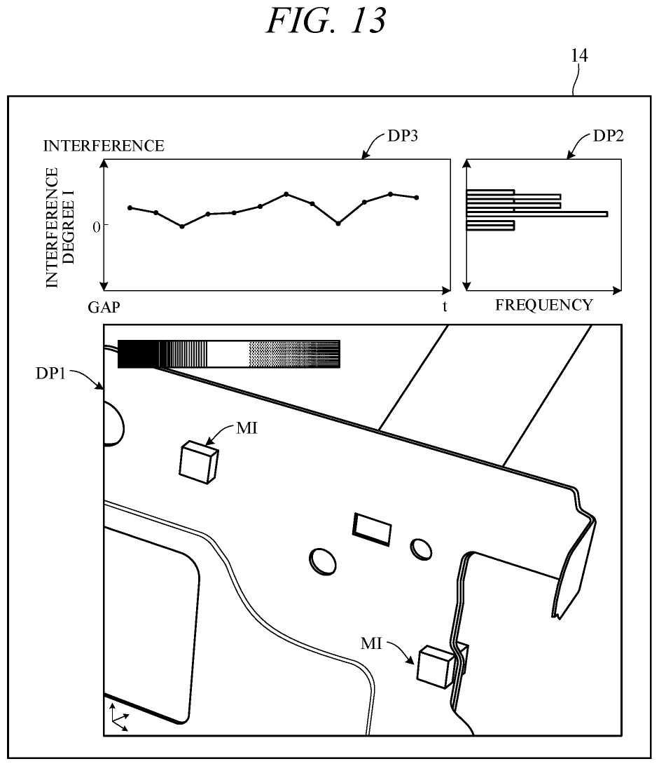

FIG. 12 and FIG. 13 are diagrams showing an example of the statistics display displayed on the display unit 14. As shown in FIG. 12, in the display unit 14, the design model is three-dimensionally displayed in a first display area DP1, and the interference degree I for each production lot or the single component error of each constituent component is displayed in histogram form in a second display area DP2. For example, when any of the indicators MI displayed in the first display area DP1 is selected by clicking through the mouse (input unit) 13, the interference degree I in the corresponding coupling portion or the single component error of each constituent component is displayed in histogram form in the second display area DP2.

The histogram display in the second display area DP2 can be switched between the interference degree I, the single component error of the first component 1, and the single component error of the second component 2 through, for example, a radio button BT. When the histogram display in the second display area DP2 is switched to the single component error of each constituent component, in association with the switching, the display of the indicator MI in the first display area DP1 is switched to a display mode corresponding to the single component error of the corresponding constituent component. For example, the directions N1 and N2 of the single component error causing interference to occur in the coupling portion are represented by the display color of the warm color system, the directions N1 and N2 of the single component error generating a gap in the coupling portion are represented by the display color of the cold color system, and the greater the magnitudes a and b of the single component error, the darker the display color is.

As shown in FIG. 13, the statistics display of the interference degree I for each production lot or the single component error of each constituent component may be the histogram display in the second display area DP2 or display in time series in the third display area DP3. As shown in FIG. 12 and FIG. 13, when the interference degree I for each production lot and the single component error of each constituent component are statistically displayed in histogram form or in time series, the error with respect to the design reference position of the finished product or each constituent component can be quantitatively evaluated for each production lot.

The interference degree calculation unit 17 of FIG. 3 can also calculate the interference degree I of the coupling portion when a combination of the production lots of the first component 1 and the second component 2 is changed and coupling is performed. For example, the first component 1 of a production lot 1A and the second component 2 of a production lot 2A are combined in a trial manufacture stage of an actual finished product, and the first component 1 of a production lot 1B and the second component 2 of a production lot 2B are combined to make a trial manufacture and measure and calculate the single component error.

In this case, based on the single component error of each constituent component calculated by the error calculation unit 16 and stored in the memory 12, for example, the interference degree I when the first component 1 of the production lot 1A and the second component 2 of the production lot 2B are combined can be calculated. This makes it possible to estimate and evaluate the accuracy of the coupling portion when the constituent components of the production lots that are not combined in the trial manufacture stage of the actual finished product are coupled to each other.

The present embodiment can achieve advantages and effects such as the following:

(1) The apparatus 10 is configured to evaluate accuracy of the coupling portion where the first component 1 having the first coupling surface 1a and the second component 2 having the second coupling surface 2a are coupled to each other through the first coupling surface 1a and the second coupling surface 2a. The apparatus 10 includes: the data acquisition unit 15 configured to acquire the design data of the first component 1 and the second component 2 and the measurement data of the first component 1 and the second component 2; the error calculation unit 16 configured to calculate the single component error between the design reference point M30 predetermined as a single point on the first coupling surface 1a and the second coupling surface 2a in the design data and the first reference point M31 on the first coupling surface 1a corresponding to the design reference point M30 in the measurement data and the single component error between the reference point M30 and the second reference point M32 on the second coupling surface 2a corresponding to the design reference point M30 in the measurement data based on the design data and the measurement data acquired by the data acquisition unit 15; the interference degree calculation unit 17 configured to calculate the interference degree I at the design reference point M30 when coupling the first component 1 and the second component 2 based on the single component error between the design reference point M30 and the first reference point M31 and the single component error between the design reference point M30 and the second reference point M32 calculated by the error calculation unit 16; and the display unit 14 is configured to display the design model of the first component 1 and the second component 2 based on the design data acquired by the data acquisition unit 15, and configured to display the indicator MI representing the interference degree I calculated by the interference degree calculation unit 17 so that the indicator MI is superimposed on the design model at the design reference point M30 (FIG. 3).

Thus, the single component error of each constituent component and the interference degree I between the constituent components with respect to the design reference point M30 in the coupling portion when the first component 1 and the second component 2 are coupled can be intuitively grasped, and the accuracy of the coupling portion can be intuitively grasped and evaluated. Since the point group data is converted into the single component error (characteristic value) for each of the design reference points M30 to compress the data capacity, time required for display when the accuracy of the coupling portion is visually evaluated can be shortened.

(2) The display unit 14 is further configured to statistically display the single component error between the design reference point M30 and the first reference point M31 and the single component error between the design reference point M30 and the second reference point M32 calculated by the error calculation unit 16 for each production lot (FIG. 12, FIG. 13). Thus, the single component error of each constituent component can be evaluated for each production lot.

(3) The interference degree calculation unit 17 is further configured to calculate the interference degree I based on the single component error between the design reference point M30 and the first reference point M31 and the single component error between the design reference point M30 and the second reference point M32 calculated by the error calculation unit 16 for each production lot and calculate the interference degree I after changing combination of the production lot of the first component 1 and the second component 2. This makes it possible to estimate and evaluate the accuracy of the coupling portion when the constituent components of the production lots that are not combined actually are coupled to each other.

(4) The display unit 14 is configured to display the indicators MI so that the indicators MI are superimposed on the design model simultaneously at the design reference points M30 (FIG. 10). Thus, since the accuracy of the coupling portion for each of the weld spots 3 can be grasped at one time, the accuracy of the entire coupling portion can be intuitively grasped and evaluated.

In the above embodiment, an example in which the first component 1 and the second component 2 are coupled by being welded has been described, but the method of coupling the first component 1 and the second component 2 to each other is not limited to welding. For example, the first component 1 and the second component 2 may be coupled to each other by fastening with bolts and nuts, bonding with an adhesive, or other methods.

Hereinabove, although the present invention has been described as an accuracy evaluation apparatus, the present invention can also be used as an accuracy evaluation method configured to evaluate the accuracy of the coupling portion where the first component 1 having the first coupling surface 1a and the second component 2 having the second coupling surface 2a are coupled to each other through the first coupling surface 1a and the second coupling surface 2a. Specifically, the accuracy evaluation method includes: the data acquisition step S1 configured to acquire the design data of the first component 1 and the second component 2 and the measurement data of the first component 1 and the second component 2; the error calculation step S5 configured to calculate the single component error between the design reference point M30 predetermined as a single point on the first coupling surface 1a and the second coupling surface 2a in the design data and the first reference point M31 on the first coupling surface 1a corresponding to the design reference point M30 in the measurement data and the single component error between the reference point M30 and the second reference point M32 on the second coupling surface 2a corresponding to the design reference point M30 in the measurement data based on the design data and the measurement data acquired in the data acquisition step S1; and the interference degree calculation step S14, S16, S17 configured to calculate the interference degree I at the design reference point M30 when coupling the first component 1 and the second component 2 based on the single component error between the design reference point M30 and the first reference point M31 and the single component error between the design reference point M30 and the second reference point M32 calculated in the error calculation step S5; and the display step S20 configured to display the design model of the first component 1 and the second component 2 based on the design data acquired in the data acquisition step S1, and configured to display the indicator MI representing the interference degree I calculated by the interference degree calculation step S14, S16, S17 so that the indicator MI is superimposed on the design model at the design reference point M30 (FIG. 5, FIG. 11).

The above embodiment can be combined as desired with one or more of the above modifications. The modifications can also be combined with one another.

According to the present invention, it becomes possible to easily grasp error with respect to a design reference position.

Above, while the present invention has been described with reference to the preferred embodiments thereof, it will be understood, by those skilled in the art, that various changes and modifications may be made thereto without departing from the scope of the appended claims.

What is claimed is:

1. An accuracy evaluation apparatus configured to evaluate an accuracy of a coupling portion where a first component having a first coupling surface and a second component having a second coupling surface are coupled to each other through the first coupling surface and the second coupling surface, comprising:
a display unit; and
a CPU and a memory coupled to the CPU, wherein
the CPU is configured to perform:
acquiring design data of the first component and the second component and premeasured measurement data of the first component and the second component;
calculating a first error between a design reference point predetermined as a single point on the first coupling surface and the second coupling surface in the design data and a first reference point on the first coupling surface corresponding to the design reference point in the measurement data and a second error between the reference point and a second reference point on the second coupling surface corresponding to the design reference point in the measurement data based on the design data and the measurement data acquired; and
calculating an interference degree at the design reference point when coupling the first component and the second component based on the first error and the second error calculated, wherein
the display unit is configured to display a design model of the first component and the second component based on the design data acquired by the CPU, and configured to display an indicator representing the interference degree calculated by the CPU so that the indicator is superimposed on the design model at the design reference point.

2. The accuracy evaluation apparatus according to claim 1, wherein
the display unit is further configured to statistically display at least one of the first error and the second error calculated by the CPU for each production lot.

3. The accuracy evaluation apparatus according to claim 2, wherein
the CPU is configured to perform:
the interference degree calculating including:
calculating the interference degree based on the first error and the second error for each production lot; and
calculating the interference degree after changing combination of the production lot of the first component and the second component.

4. The accuracy evaluation apparatus according to claim 1, wherein
the display unit is configured to display a plurality of the indicator so that the plurality of the indicator is superimposed on the design model simultaneously at a plurality of the design reference point.

5. The accuracy evaluation apparatus according to claim 1, wherein
the design data of the first component, the second component and the design reference point and the measurement data of the first component and the second component are specified in a single predetermined three-dimensional fixed coordinate system, wherein
the CPU is configured to perform:
the error calculating including calculating the first error and the second error in the coordinate system; and
the interference degree calculating including calculating the interference degree in the coordinate system, wherein
the display unit is configured to display the design model of the first component and the design model of the second component in the coordinate system.

6. An accuracy evaluation apparatus configured to evaluate an accuracy of a coupling portion where a first component having a first coupling surface and a second component having a second coupling surface are coupled to each other through the first coupling surface and the second coupling surface, comprising:
a display unit; and
a CPU and a memory coupled to the CPU, wherein
the CPU is configured to function as:
a data acquisition unit configured to acquire design data of the first component and the second component and premeasured measurement data of the first component and the second component;
an error calculation unit configured to calculate a first error between a design reference point predetermined as a single point on the first coupling surface and the second coupling surface in the design data and a first reference point on the first coupling surface corresponding to the design reference point in the measurement data and a second error between the reference point and a second reference point on the second coupling surface corresponding to the design reference point in the measurement data based on the design data and the measurement data acquired by the data acquisition unit; and
an interference degree calculation unit configured to calculate an interference degree at the design reference point when coupling the first component and the second component based on the first error and the second error calculated by the error calculation unit, wherein
the display unit is configured to display a design model of the first component and the second component based on the design data acquired by the CPU, and configured to display an indicator representing the interference degree calculated by the CPU so that the indicator is superimposed on the design model at the design reference point.

7. The accuracy evaluation apparatus according to claim 6, wherein
the display unit is further configured to statistically display at least one of the first error and the second error calculated by the CPU for each production lot.

8. The accuracy evaluation apparatus according to claim 7, wherein
the interference degree calculation unit is further configured to calculate the interference degree based on the first error and the second error for each production lot and calculate the interference degree after changing combination of the production lot of the first component and the second component.

9. The accuracy evaluation apparatus according to claim 6, wherein
the display unit is configured to display a plurality of the indicator so that the plurality of the indicator is superimposed on the design model simultaneously at a plurality of the design reference point.

10. The accuracy evaluation apparatus according to claim 6, wherein
the design data of the first component, the second component and the design reference point and the measurement data of the first component and the second component are specified in a single predetermined three-dimensional fixed coordinate system, wherein
the error calculation unit is configured to calculate the first error and the second error in the coordinate system, wherein
the interference degree calculation unit is configured to calculate the interference degree in the coordinate system, wherein
the display unit is configured to display the design model of the first component and the design model of the second component in the coordinate system.

11. An accuracy evaluation method configured to evaluate an accuracy of a coupling portion where a first component having a first coupling surface and a second component having a second coupling surface are coupled to each other through the first coupling surface and the second coupling surface, comprising:
acquiring design data of the first component and the second component and premeasured measurement data of the first component and the second component;
calculating a first error between a design reference point predetermined as a single point on the first coupling surface and the second coupling surface in the design data and a first reference point on the first coupling surface corresponding to the design reference point in the measurement data and a second error between the reference point and a second reference point on the second coupling surface corresponding to the design reference point in the measurement data based on the design data and the measurement data acquired;
calculating an interference degree at the design reference point when coupling the first component and the second component based on the first error and the second error calculated;
displaying a design model of the first component and the second component based on the design data acquired; and
displaying an indicator representing the interference degree calculated so that the indicator is superimposed on the design model at the design reference point.
